(19) United States
(12) Patent Application Publication
(10) Pub. No.: US 2021/0045269 A1
(43) Pub. Date: Feb. 11, 2021

(54) ELECTROMAGNETIC WAVE ABSORBING SHEET AND METHOD FOR PRODUCING SAME

(71) Applicant: DUPONT TEIJIN ADVANCED PAPERS (JAPAN), LTD., Tokyo (JP)

(72) Inventors: Shinji NARUSE, Chiyoda-ku, Tokyo (JP); Tatsushi FUJIMORI, Chiyoda-ku, Tokyo (JP); Koichi UKIGAYA, Chiyoda-ku, Tokyo (JP); Yasunori TANAKA, Chiyoda-ku, Tokyo (JP)

(73) Assignee: DUPONT TEIJIN ADVANCED PAPERS (JAPAN), LTD., Tokyo (JP)

(21) Appl. No.: 16/976,296

(22) PCT Filed: Jan. 29, 2019
(86) PCT No.: PCT/JP2019/002882

§ 371 Date: Aug. 27, 2020

(30) Foreign Application Priority Data
Mar. 30, 2018 (JP) 2018-067119
May 22, 2018 (JP) 2018-097641

(51) Int. Cl. H05K 9/00; B32B 7/025; H01L 23/552

(52) U.S. Cl. CPC H05K 9/0088; H01L 2924/3025; H01L 23/552; B32B 7/025

(57) ABSTRACT

The present invention provides an electromagnetic wave absorbing sheet which contains conductive short fibers and an insulating material, and which exhibits particularly high radio wave absorbing properties in one direction.

### TECHNICAL FIELD

The present invention relates to an electromagnetic wave absorbing sheet.

### BACKGROUND TECHNOLOGY

With the development of an advanced information society and the advent of a multimedia society, electromagnetic interference, in which electromagnetic waves generated from electronic equipment adversely affect other equipment and the human body, is becoming a major social problem. As the electromagnetic wave environment becomes worse and worse, various electromagnetic wave absorbing sheets have been provided to absorb the electromagnetic waves corresponding to each of these (see Japanese Unexamined Patent Application, Publication No. 2004-140335). For example, for absorption of electromagnetic waves, an electromagnetic wave absorber using ferrite or the like, and an electromagnetic wave absorber using carbon black or the like, have been provided.

However, these electromagnetic wave absorbers absorb electromagnetic waves only in a specific absorption wavelength range, and cannot cope with a wide wavelength range. For example, an electromagnetic wave absorber using ferrite or the like absorbs a band of several GHz, but cannot absorb a band of several tens of GHz. On the other hand, an electromagnetic wave absorber using carbon black or the like can absorb a band of several tens of GHz, but is not suitable for absorption in a band of several GHz. Actually, in order to satisfy conditions such as a desired absorption frequency and a maximum absorption amount at the frequency, a method of appropriately selecting an electromagnetic wave absorber from a plurality of types of radio wave absorbers is used, making practical use of the electromagnetic wave absorber difficult.

Furthermore, high frequency equipment such as generators, motors, inverters, converters, printed circuit boards, and cables, requiring high efficiency and a large capacity, is becoming small in size and light in weight. Accordingly, there is a demand for an electromagnetic wave absorbing material with high heat resistance which is capable of withstanding the heat generation of a conductive wire caused by the flow of a high frequency current. In particular, in electric and electronic equipment such as inverters and motors, to which a high voltage is to be applied, since the temperature of the equipment rises greatly, a material having high heat resistance is required.

Furthermore, the size and weight of high frequency equipment are being reduced, and in particular, electromagnetic waves radiating with a specific directivity the vicinity of an electromagnetic wave generating source are increasing. Accordingly, there is a demand for an electromagnetic wave absorbing sheet exhibiting a strong electromagnetic wave absorption property in a specific direction even while having a small size and light weight.

### SUMMARY OF INVENTION

An object of the present invention is to provide an electromagnetic wave absorbing sheet capable of absorbing an electromagnetic wave with a wide range and a high frequency, having high heat resistance, and having a light weight.

In order to solve the above-mentioned problems, the present inventors have conducted extensive studies. As a result, they have found that the above-mentioned problems can be solved by an electromagnetic wave absorbing sheet comprising a conductive short fiber and an insulating material, and exhibiting a particularly large radio wave absorption property in one direction, and an electromagnetic wave absorbing multilayer sheet obtained by stacking the electromagnetic wave absorbing sheets asymmetrically and in different directions, and they have completed the present invention.

One embodiment of the present invention is an electromagnetic wave absorbing sheet comprising a conductive short fiber and an insulating material, and exhibiting a particularly large radio wave absorption property in one direction. Preferably, in the electromagnetic wave absorbing sheet, an electromagnetic wave absorption rate in at least one direction of an electromagnetic wave having a frequency range of 14 to 20 GHz is 99% or more. Further preferably, the insulating material is polymetaphenylene isophthalamide. Still further preferably, in the electromagnetic wave absorbing sheet, a change rate in at least one direction of an electromagnetic wave absorption rate at a frequency of 5 GHz after heat treatment at 300° C. for 30 minutes with respect to an electromagnetic wave absorption rate before the heat treatment is 10% or less, and more preferably 1% or less. Further preferably, the sheet comprising the conductive short fiber and the insulating material is oriented.

A further embodiment is a method for producing the electromagnetic wave absorbing sheet, the method comprising moving a sheet comprisinga conductive short fiber and an insulating material in one direction, and simultaneously reducing porosity.

A further embodiment is an electromagnetic wave absorbing multilayer sheet comprising the electromagnetic wave absorbing sheets stacked in different directions and asymmetrically. Preferably, the electromagnetic wave absorbing multilayer sheet comprises the electromagnetic wave absorbing sheets stacked in an orthogonal direction and asymmetrically. Preferably, in the electromagnetic wave absorbing multilayer sheet, the electromagnetic wave absorbing sheets are stacked and then pressed. Preferably, the electromagnetic wave absorbing multilayer sheet has an electromagnetic wave absorption rate in one direction of an electromagnetic wave having a frequency range of 14 to 20 GHz of 99% or more. Preferably, the electromagnetic wave absorbing multilayer sheet has an electromagnetic wave absorption rate in at least one direction of an electromagnetic wave having a frequency range of 6 to 20 GHz of 99% or more. Preferably, in the electromagnetic wave absorbing multilayer sheet, a change rate in at least one direction of an electromagnetic wave absorption rate at a frequency of 5 GHz after heat treatment at 300° C. for 30 minutes with respect to an electromagnetic wave absorption rate before the heat treatment is 10% or less, and more preferably 1% or less.

A further embodiment is an electric and electronic circuit comprising the electromagnetic wave absorbing sheet or the electromagnetic wave absorbing multilayer sheet being mounted.

A further embodiment is a cable comprising the electromagnetic wave absorbing sheet or the electromagnetic wave absorbing multilayer sheet being mounted.

Hereinafter, the present invention is described in more detail.

### DESCRIPTION OF EMBODIMENTS

### (Conductive Short Fiber)

Examples of a conductive short fiber to be used in the present invention include conductive short fibers being a fiber product having a conductivity in a wide range, from a conductor having a volume resistivity of about 10⁻¹ Ω·cm or less to a semiconductor having a volume resistivity of about 10⁻¹ to 10⁸ Ω·cm, and having a relationship between the fiber diameter and the fiber length represented by the following formula.

100≤fiber length/fiber diameter≤20000

Examples of such a conductive short fiber include, but are not limited to, materials having homogeneous conductivity, such as metal fibers and carbon fibers, or materials obtained by mixing a conductive material and a non-conductive material to exhibit conductivity as a whole, for example, metal plated fibers, metal powder mixed fibers, and carbon black mixed fibers. Among these, in the present invention, it is preferable to use carbon fibers. The carbon fibers used in the present invention are preferably fibers obtained by firing a fibrous organic matter at a high temperature in an inert atmosphere, followed by carbonization. Carbon fibers are generally classified roughly into ones obtained by firing polyacrylonitrile (PAN) fibers and ones obtained by pitch spinning followed by firing. In addition to these, there are also carbon fibers produced by spinning resins such as rayon and phenol, followed by firing, and such fibers can also be used in the present invention. It is also possible to prevent heat cutting at the time of firing by using oxygen and the like to carry out oxidation cross-linking treatment prior to firing.

The fiber length of the conductive short fiber to be used in the present invention is selected from the range of 1 mm to 20 mm.

In the selection of a conductive short fiber, it is more preferable to use materials having a high conductivity and exhibiting good dispersion in the wet paper making method to be described later. Furthermore, when the porosity is reduced along one direction, the conductive short fiber is deformed and cut and thereby an inductor is formed, and an electromagnetic wave absorbing sheet absorbing electromagnetic waves with a wide range and high frequency can be obtained.

The content of the conductive short fiber in the electromagnetic wave absorbing sheet is preferably 1 wt. % to 40 wt. %, and more preferably 3 wt. % to 20 wt. % with respect to the total weight of the sheet.

### (Insulating Material)

In the present invention, an insulating material is a material having a volume resistivity of 1×10⁷ Ω·cm or more, and having a dielectric loss tangent of 0.01 or more at 20° C. and a frequency of 60 Hz, and having a dielectric constant of 4 or less at 20° C. and a frequency of 60 Hz, in order to absorb electromagnetic waves using dielectric loss of the insulating material itself. However, the insulating material is not necessarily limited to this.

The insulating material having a dielectric loss tangent of 0.01 or more is a substance having a dielectric loss tangent of 0.01 or more under conditions wherein at 20° C. electromagnetic waves with a frequency of 60 Hz are radiated. In the insulating material, in general, the larger the dielectric loss represented by the following formula is, the larger the absorption amount of the electromagnetic wave becomes.

P=E²×tan δ×2πf×εᵣ×ε₀×S/d (W)

In the formula, P represents dielectric loss (W), E represents voltage (V), tan δ represents a dielectric loss tangent of the insulating material, f represents frequency (Hz), εᵣ represents relative permittivity of the insulating material, ε₀ represents permittivity of vacuum (8.85418782×10⁻¹² (m⁻³kg⁻¹s⁴A²)), S represents a contact area (m²) of the conductive substance and the insulating material, and d represents a distance (m) between the conductive substances.

Since the dielectric loss is proportional to the contact area of the conductive material and the insulating material as shown in the above formula, the shape of the insulating material is preferably, but is not limited to, a film shaped microparticle whose contact area increases.

When the relative permittivity of the insulating material at 20° C. and a frequency of 60 Hz is 4 or less, it is difficult for the electromagnetic wave to be reflected, which is considered to be suitable for the insulating material of the present invention.

Examples of the insulating material include, but are not limited to, polymetaphenylene isophthalamide and copolymers thereof, polyvinyl chloride, polymethyl methacrylate, methyl methacrylate/styrene copolymers, polychlorotrifluoroethylene, polyvinylidene fluoride,polyvinylidene chloride, Nylon 6, and Nylon 66, all of which have a dielectric loss tangent of 0.01 or more at 20° C. and 60 Hz.

Among these insulating materials, polymetaphenylene isophthalamide and copolymers thereof, polymethyl methacrylate, methyl methacrylate/styrene copolymer, polychlorotrifluoroethylene, and Nylon 66 are considered to be suitable as the insulating material of the present invention because their relative permittivity at 20° C. and a frequency of 60 Hz is as small as 4 or less, making it difficult for electromagnetic waves to be reflected.

Among these insulating materials, fibrids of polymetaphenylene isophthalamide (hereinafter, referred to as aramid fibrids) and/or short fibers of polymetaphenylene isophthalamide (hereinafter, aramid short fibers) are preferably used from the viewpoint that they have characteristics such as good formation processability, flame retardancy, and heat resistance. In particular, fibrids of polymetaphenylene isophthalamide are preferably used from the viewpoint that the contact area with conductive material is increased, the above-described dielectric loss is increased, and the absorption amount of the electromagnetic wave is increased from the shape of the film shaped microparticles.

The content of the insulating material in the electromagnetic wave absorbing sheet is preferably 60 wt. % to 99 wt. %, and more preferably 80 wt. % to 90 wt. % with respect to the total weight of the sheet.

### (Electromagnetic Wave Absorbing Sheet Exhibiting a Particularly Large Radio Wave Absorption Property in One Direction)

In the present invention, the radio wave absorption property being particularly large in one direction means that a ratio of the absolute value of the minimum value of the transmission attenuation rate Rtp (mentioned later) in at least one direction of the sheet to the absolute value of the minimum value of the Rtp in a direction perpendicular to the one direction is 1.2 or more. The ratio is preferably 1.5 or more.

The electromagnetic wave absorbing sheet exhibiting a particularly large radio wave absorption property in one direction of the present invention can be produced generally by a method of mixing the above-described conductive short fiber and an insulating material with each other, followed by forming a sheet, then moving the obtained sheet in one direction and simultaneously reducing the porosity, or orienting the conductive short fiber in one direction with a Fourdrinier paper making machine, a cylinder paper making machine, or an inclined paper making machine. Specific examples applicable include, for example, a method of blending a conductive short fiber and the aramid fibrid and short fiber mentioned above in a dry method, followed by forming a sheet by use of air stream, and a method of dispersing and mixing a conductive short fiber and the aramid fibrid and short fiber mentioned above in a liquid medium, and discharging the obtained dispersion product onto a liquid permeable support such as a mesh or a belt to form a sheet, followed by removing the liquid for drying. Among these, a so-called wet paper making method using water as a medium is preferable.

In the wet paper making method, it is common to feed an aqueous slurry of single one of or a mixture of at least conductive short fiber and the aramid fibrid and aramid short fiber described above to a paper making machine for dispersion, followed by dehydration, dewatering, and drying operations to wind it up as a sheet. Examples of the paper making machine usable can include Fourdrinier paper making machines, cylinder paper making machines, inclined paper making machines, and combination paper making machines combining these. In the case of production with a combination paper making machine, it is also possible to obtain a composite sheet composed of several paper layers by sheet-forming and coalescing aqueous slurries having different blending ratios.

Furthermore, in the electromagnetic wave absorbing sheet exhibiting a particularly large radio wave absorption property in one direction according to the present invention, the inductor is formed more easily in the case where the conductive short fibers are oriented in one direction with a Fourdrinier paper making machine, a cylinder paper making machine, or an inclined paper making machine when the sheet is moved in one direction, and simultaneously, the porosity is reduced, (described later), and the conductive short fibers are deformed and cut.

Additives such as a dispersibility improver, a defoaming agent, a paper strength enhancer, or the like, may be used if necessary in wet paper making. However, it is necessary to pay attention to their use so as not to hinder the object of the present invention.

Furthermore, as long as the object of the present invention is not impaired, the electromagnetic wave absorbing sheet of the present invention may comprise other fibrous components in addition to the above components. Note that the above additives and other fibrous components used are preferably 20 wt. % or less with respect to the total weight of the sheet.

When the thus obtained sheet is subjected to, for example, compression between a pair of rotating metal rolls, the sheet can be moved in one direction and simultaneously made to have a reduced porosity. When the porosity is reduced along one direction, the conductive short fiber is deformed and cut, so that an inductor is formed. Thus, it is possible to obtain an electromagnetic wave absorbing sheet exhibiting a particularly large radio wave absorption property in one direction with a wide range and high frequency (preferably, an electromagnetic wave absorption rate in at least one direction of an electromagnetic wave having a frequency range of 14 to 20 GHz is 90% or more). Furthermore, in the electromagnetic wave absorbing sheet, the change rate in at least one direction of the electromagnetic wave absorption rate at a frequency of 5 GHz at 300° C. for 30 minutes with respect to that before heat treatment is preferably 10% or less, and more preferably 1% or less.

Reduction of the porosity in the present invention means reducing the porosity to ¾ or less of the porosity before reduction of the porosity by, for example, a method of compression between the pair of rotating metal rolls. Specifically, when the porosity before reduction is 80%, the porosity after the reduction is made to be 60% or less, and preferably 55% or less.

Conditions of compression processing for reducing the porosity along one direction are not particularly limited as long as conductive short fibers are deformed and cut along one direction. For example, when compression is carried out between the pair of rotating metal rolls, for example, the surface temperatures of the metal rolls is 100 to 400° C., and the linear pressure between the metal rolls is in a range of 50 to 1000 kg/cm. In order to obtain high tensile strength and surface smoothness, the roll temperature is preferably 270° C. or more, and more preferably 300° C. to 400° C. Furthermore, the linear pressure is preferably 100 to 500 kg/cm. Furthermore, for forming an inductor oriented in one direction, the movement speed of the sheet is preferably 1 m/minute or more, and preferably 2 m/minute or more.

The above-mentioned compression treatment maybe carried out at a plurality of times. Compression treatment may be carried out by stacking a plurality of sheet-shaped products obtained by the above-described method.

In addition, a plurality of sheets obtained by the above-described method may be stacked to form an electromagnetic wave absorbing multilayer sheet, stacked and then bonded to each other by pressing or hot-pressing, or attached to each other using an adhesive agent or the like to adjust the electromagnetic wave transmission suppression performance and the thickness. Usually, the direction of the electric field of the electromagnetic wave is orthogonal to the direction of the magnetic field of the electromagnetic wave. When the sheets are stacked in different directions, preferably in an orthogonal direction, the directions of both the electric field and magnetic field of the absorbed electromagnetic wave can be arranged in parallel to the inductor. Furthermore, as in the present invention, when an electromagnetic wave is absorbed using the dielectric loss of the conductive short fiber, the asymmetrical stacking of sheets, i.e. arranging a sheet in which the direction of the electric field is in parallel to the direction of the inductor near to the electromagnetic wave generating source, and a sheet in which the direction of the magnetic field is in parallel to the direction of the inductor far from the electromagnetic wave generating source, exhibits a higher electromagnetic wave absorption property because the electromagnetic wave absorption property is not weakened by the counter electromotive force generated from the inductor in the sheet (preferably, an electromagnetic wave absorption rate in at least one direction of an electromagnetic wave with a frequency range of 14 to 20 GHz is 99% or more, more preferably, an electromagnetic wave absorption rate in at least one direction of an electromagnetic wave with a frequency range of 6 to 20 GHz is 99% or more). Furthermore, the change rate in at least one direction of the electromagnetic wave absorption rate at a frequency of 5 GHz at 300° C. for 30 minutes with respect to that before heat treatment is preferably 10% or less, and more preferably 1% or less.

The electromagnetic wave absorbing sheet or the electromagnetic wave absorbing multilayer sheet of the present invention has excellent characteristics such as: (1) having an electromagnetic wave absorption property, (2) exhibiting a particularly large radio wave absorption property in one direction and therefore being capable of selectively absorbing an electromagnetic wave in a specific direction, (3) expressing the characteristics (1) and (2) in a wide range of frequencies range including a high frequency, (4) having heat resistance and flame retardancy, and (5) having good processability, and can be suitably used as an electromagnetic wave suppression sheet of electric and electronic equipment, particularly electronic equipment in hybrid cars and electric automobiles requiring weight reduction. In particular, when the electromagnetic wave absorbing sheet or the electromagnetic wave absorbing multilayer sheet of the present invention are mounted on, for example, electric and electronic circuits such as a printed circuit board, or a cable via insulating products, the generation of electromagnetic waves is suppressed. Note here that when the electric and electronic circuit is covered with a housing, for example, metal, resin, and the like, the electromagnetic wave absorbing sheet or the electromagnetic wave absorbing multilayer sheet of the present invention may be fixed to be mounted to the inside of the housing with, for example, an adhesive agent, and the like. In this case, an insulated product (air, resin, and the like) is preferably interposed between the electric and electronic circuit and the electromagnetic wave absorbing sheet. When the electromagnetic wave absorbing sheet of the present invention is produced, in the above-described pressing processing, an insulating sheet can be previously stacked and pressed to insulate the surface. Note here that the above-described insulating sheet means a sheet comprising the insulating material described above.

Hereinafter, the present invention is described further specifically with reference to Examples. These Examples are merely illustrative, and are not intended at all to limit the content of the present invention.

### EXAMPLES

### (Measurement Method)

### (1) Sheet Mark, Thickness, Density, and Porosity

Measurement was carried out in accordance with JIS C 2300-2, and a density was calculated by (mark/thickness). A porosity was calculated from the density, a composition of a raw material, and a specific gravity of the raw material.

### (2) Tensile Strength

The width was 15 mm, the chuck interval was 50 mm, and the tensile rate was 50 mm/min.

### (3) Dielectric Constant and Dielectric Loss Tangent

Measurement was carried out in accordance with JIS K6911.

### (4) Electromagnetic Wave Absorption Performance

Using a near-field electromagnetic wave evaluation system in accordance with IEC 62333, a sample sheet was laminated on a microstripline (MSL) with a polyethylene film (thickness: 38 μm) sandwiched, 500 g of load was applied to the sheet with an insulating weight, and electric power of the reflected wave S11 and electric power of transmitted wave S21 for the incident wave of 50 MHz to 20 GHz were measured using a network analyzer.

From the following formula, the transmission attenuation rate Rtp was obtained.

Rtp=10×log[10^{S21/10}/(1-10^{S11/10})] (dB)
[10^{S21/10}/(1-10^{S11/10})] represents an electromagnetic wave attenuation rate; and
1-[10^{S21/10}/(1-10^{S11/10})] represents an electromagnetic wave absorption rate.
When Rtp=−20 (dB) is satisfied, the electromagnetic wave absorption rate is 99%.
When Rtp<−20 (dB) is satisfied, the electromagnetic wave absorption rate is more than 99%.

It can be said that the smaller Rtp is, the larger the attenuation of electromagnetic wave is and the higher the electromagnetic wave absorption performance is.

Furthermore, after the sample sheet was heat-treated at 300° C. for 30 minutes, the change rate Cr of the electromagnetic wave absorption rate at a frequency of 5 GHz was obtained from the following formula.

Cr=|(electromagnetic wave absorption rate after heat treatment−electromagnetic wave absorption rate before heat treatment)/electromagnetic wave absorption rate before heat treatment|

It can be said that the smaller the Cr is, the higher the heat resistance is.

### (Preparation of Raw Material)

A fibrid of polymetaphenylene isophthalamide (hereinafter referred to as the “meta-aramid fibrid”) was produced using the pulp particle production apparatus (wet type precipitator) formed by a combination of a stator and a rotor described in Japanese Patent Application Publication No. Sho 52-15621. This was treated with a beating machine to adjust the length weighted average fiber length to 0.9 mm (freeness: 200 cm³). Meanwhile, as a short fiber of polymetaphenylene isophthalamide, a meta-aramid fiber manufactured by Du Pont (Nomex (registered trademark), single thread fineness: 2.2 dtex) was cut to 6 mm in length (hereinafter referred to as the “meta-aramid short fiber”), and to be used as a raw material for papermaking.

### (Measurement of Dielectric Constant and Dielectric Loss Tangent)

A cast film of polymetaphenylene isophthalamide was produced, and the dielectric constant and the dielectric loss tangent were measured by the bridge method at 20° C. The measurement results are shown in Table 1.

TABLE 1

| Frequency | Relative | Dielectric |
|---|---|---|
| Hz | Permittivity | Loss Tangent |
| 60 | 2.81 | 0.013 |
| 1k | 2.74 | 0.015 |
| 1M | 2.79 | 0.028 |

### Examples 1 to 5

### (Production of Sheet)

Each the meta-aramid fibrid (having a volume resistivity of 1×10¹⁶ Ω·cm), and the meta-aramid short fiber (having a volume resistivity of 1×10¹⁶ Ω·cm), prepared as described above, and the carbon fiber (manufactured by Toho Tenax Co., Ltd., and having a fiber length of 3 mm, a single fiber diameter of 7 μm, a fineness of 0.67 dtex, and a volume resistivity of 1.6×10⁻³ Ω·cm) were dispersed in water to produce slurries. These slurries were mixed such that the blend ratios of the meta-aramid fibrid, the meta-aramid short fiber, and the carbon fiber were those shown in Table 2, and treated using a Tappi type hand paper making machine (having a cross sectional area of 325 cm²) to produce sheet-shaped products (porosity of 79%), while a stream of water was added and the orientation property (the ratio of longitudinal tensile strength to transverse tensile strength) was adjusted. The direction of the stream of water is defined as a longitudinal direction, and the direction perpendicular to the direction of the stream of water is defined as a transverse direction. Next, the obtained sheets were moved in the longitudinal direction between a pair of the metal calendar rolls, and compressed in the conditions shown in Table 2 to obtain sheet-shaped products.

Furthermore, the sheets mentioned above were stacked in the conditions shown in Table 2.

Table 2 shows the main characteristic values of the sheets obtained in this way.

### (The Specific Gravity of the Raw Material was 1.38 for the Meta-Aramid Fibrid, 1.38 for the Meta-Aramid Short Fiber, and 1.8 for the Carbon Fiber.)

TABLE 2

| | | Examples | | | | |
|---|---|---|---|---|---|---|
| Characteristics | Unit | 1 | 2 | 3 | 4 | 5 |
| Raw material | wt. % | | | | | |
| composition | | | | | | |
| Meta-aramid | | 50 | 50 | 50 | 50 | 50 |
| fibrid | | | | | | |
| Meta-aramid short | | 45 | 45 | 45 | 45 | 45 |
| fiber | | | | | | |
| Carbon fiber | | 5 | 5 | 5 | 5 | 5 |
| Compression | | | | | | |
| conditions | | | | | | |
| Roll temperature | ° C. | 300 | 300 | 300 | 300 | 300 |
| Linear pressure | kgf/cm | 200 | 200 | 200 | 200 | 200 |
| Speed | m/min | 2 | 2 | 2 | 2 | 2 |
| Basic weight | g/m² | 41 | 123 | 123 | 123 | 123 |
| Thickness | μm | 59 | 177 | 177 | 177 | 177 |
| Density | g/cm³ | 0.69 | 0.69 | 0.69 | 0.69 | 0.69 |
| Porosity | % | 51 | 51 | 51 | 51 | 51 |
| Longitudinal | kgf/15 mm | 9.7 | 29.1 | | | |
| tensile strength | | | | | | |
| Traverse tensile | kgf/15 mm | 2.4 | 7.2 | | | |
| strength | | | | | | |
| Stacking method | | | | | | |
| (sequentially from | | — | Lo* | Lo* | Lo* | Lo* |
| near MSL, | | | Lo* | Lo* | Tr* | Tr* |
| MSL is in parallel | | | Lo* | Tr* | Tr* | Lo* |
| to Lo*) | | | | | | |
| MSL is in parallel | | | | | | |
| to Lo* | | | | | | |
| Frequency at | GHz | None | 7.2-20 | 7.2-20 | 8.4-20 | 6.6-20 |
| Rtp < −20 dB | | | | | | |
| Rtp Minimum value | dB | −18 | −31 | −31 | −34 | −36 |
| Frequency at the time | GHz | 18.4 | 18.4 | 16.3 | 18.4 | 16.1 |
| Cr at frequency | % | 7.0 | 0.3 | 0.3 | 0.5 | 0.3 |
| of 5 GHz before and | | | | | | |
| after heat | | | | | | |
| treatment at 300° C. | | | | | | |
| for 30 min | | | | | | |
| MSL is in parallel | | | | | | |
| to Tr* | | | | | | |
| Frequency at | GHz | 13-20 | 7.2-20 | 5.7-20 | 5.9-20 | 6.4-20 |
| Rtp < −20 dB | | | | | | |
| Rtp minimum value | dB | −29 | −48 | −59 | −56 | −46 |
| Frequency at the | GHz | 19.2 | 19 | 18.3 | 16.2 | 18.9 |
| time | | | | | | |
| Cr at frequency | % | 0.3 | 0.3 | 0.3 | 0.3 | 0.3 |
| of 5 GHz before and | | | | | | |
| after heat | | | | | | |
| treatment at 300° C. | | | | | | |
| for 30 min | | | | | | |
| Ratio of absolute | | 1.61 | 1.55 | 1.90 | 1.65 | 1.28 |
| value of Rtp | | | | | | |
| minimum value | | | | | | |

Lo*: longitudinal direction
Tr*: traverse direction

### Comparative Example

### (Production of Sheet)

Each the meta-aramid fibrid and the meta-aramid short fiber prepared as described above, and the carbon fiber (manufactured by Toho Tenax Co., Ltd., and having a fiber length of 3 mm, a single fiber diameter of 7 μm, a fineness of 0.67 dtex, and a volume resistivity of 1.6×10⁻³ Ω·cm) were dispersed in water to prepare a slurry.

This slurry was mixed such that the blend ratios of the meta-aramid fibrid, the meta-aramid short fiber, and the carbon fiber were those shown in Table 3, and treated using a Tappi type hand paper making machine (cross sectional area: 325 cm²) to produce a sheet-shaped product shown in Table 3.

Next, the obtained sheet was subjected to compression pressing with a pair of metal calendar rolls under the conditions shown in Table 3 to obtain a sheet-shaped product. The direction property is not particularly limited, but one direction is defined as a longitudinal direction, and a direction perpendicular to the longitudinal direction is defined as a transverse direction.

Table 3 shows the main characteristic values of the sheet obtained in this way.

TABLE 3

| | | Comparative |
|---|---|---|
| Characteristics | Unit | Example |
| Raw material composition | wt. % | |
| Meta-aramid fibrid | | 50 |
| Meta-aramid short fiber | | 45 |
| Carbon fiber | | 5 |
| Basic weight | g/m² | 41 |
| Thickness | μm | 58 |
| Density | g/cm³ | 0.71 |
| Porosity | % | 49 |
| Longitudinal tensile strength | kgf/15 mm | 6.1 |
| Traverse tensile strength | kgf/15 mm | 6.1 |
| Compression conditions | | |
| Press temperature | ° C. | 300 |
| Surface pressure | kgf/cm | 2000 |
| Time | m/min | 1 |
| MSL is in parallel to longitudinal | | |
| direction | | |
| Frequency at Rtp <−20 dB | GHz | 15.5-20 |
| Rtp minimum value | dB | −23 |
| Frequency at the time | GHz | 19.8 |
| Cr at frequency of 5 GHz before and | % | 5.8 |
| after heat treatment at 300° C. for | | |
| 30 min | | |
| MSL is in parallel to traverse | | |
| direction | | |
| Frequency at Rtp <−20 dB | GHz | 16-20 |
| Rtp minimum value | dB | −22 |
| Frequency at the time | GHz | 18.4 |
| Cr at frequency of 5 GHz before and | % | 6 |
| after heat treatment at 300° C. for | | |
| 30 min | | |
| Ratio of absolute value of Rtp | | 1.05 |
| minimum value | | |

As shown in Table 2, the electromagnetic wave absorbing sheets of Examples 1 to 5 showed an excellent property for electromagnetic wave absorption characteristics in at least one direction with a wide range and frequencies including a high frequency to 20 GHz. In particular, the sheet stacked in different directions and asymmetrically shown in Examples 3 and 4 showed excellent characteristics.

On the contrary, as shown in Table 3, the sheet of the Comparative Example had a narrow frequency range exhibiting an electromagnetic wave absorption property, and was not sufficient as the objective electromagnetic wave absorbing sheet.

1. An electromagnetic wave absorbing sheet comprising a conductive short fiber and an insulating material, and exhibiting a particularly large radio wave absorption property in one direction.

2. The electromagnetic wave absorbing sheet according to claim 1, wherein an electromagnetic wave absorption rate in at least one direction of an electromagnetic wave having a frequency range of 14 to 20 GHz is 99% or more.

3. The electromagnetic wave absorbing sheet according to claim 1, wherein the insulating material is polymetaphenylene isophthalamide.

4. The electromagnetic wave absorbing sheet according to claim 1, wherein a change rate in at least one direction of an electromagnetic wave absorption rate at a frequency of 5 GHz after heat treatment at 300° C. for 30 minutes with respect to an electromagnetic wave absorption rate before the heat treatment is 10% or less.

5. The electromagnetic wave absorbing sheet according to claim 1, wherein a change rate in at least one direction of an electromagnetic wave absorption rate at a frequency of 5 GHz after heat treatment at 300° C. for 30 minutes with respect to an electromagnetic wave absorption rate before the heat treatment is 1% or less.

6. The electromagnetic wave absorbing sheet according to claim 1, wherein the sheet comprising the conductive short fiber and the insulating material is oriented.

7. A method for producing the electromagnetic wave absorbing sheet according to claim 1, the method comprising moving a sheet comprising a conductive short fiber and an insulating material in one direction and simultaneously reducing porosity.

8. An electromagnetic wave absorbing multilayer sheet comprising electromagnetic wave absorbing sheets according to claim 1 stacked in different directions and asymmetrically.

9. An electromagnetic wave absorbing multilayer sheet comprising electromagnetic wave absorbing sheets according to claim 1 stacked in an orthogonal direction and asymmetrically.

10. The electromagnetic wave absorbing multilayer sheet according to claim 8, wherein the electromagnetic wave absorbing sheets are stacked and then pressed.

11. The electromagnetic wave absorbing multilayer sheet according to claim 8, wherein the electromagnetic wave absorbing sheets are stacked and then hot-pressed.

12. The electromagnetic wave absorbing multilayer sheet according to claim 8, wherein an electromagnetic wave absorption rate in at least one direction of the electromagnetic wave having a frequency range of 14 to 20 GHz is 99% or more.

13. The electromagnetic wave absorbing multilayer sheet according to claim 8, wherein an electromagnetic wave absorption rate in at least one direction of the electromagnetic wave having a frequency range of 6 to 20 GHz is 99% or more.

14. The electromagnetic wave absorbing multilayer sheet according to claim 8, wherein a change rate in at least one direction of an electromagnetic wave absorption rate at a frequency of 5 GHz after heat treatment at 300° C. for 30 minutes with respect to an electromagnetic wave absorption rate before the heat treatment is 10% or less.

15. The electromagnetic wave absorbing multilayer sheet according to claim 8, wherein a change rate in at least one direction of an electromagnetic wave absorption rate at a frequency of 5 GHz after heat treatment at 300° C. for 30 minutes with respect to an electromagnetic wave absorption rate before the heat treatment is 1% or less.

16. An electric and electronic circuit comprising the electromagnetic wave absorbing sheet according to claim 1.

17. A cable comprising the electromagnetic wave absorbing sheet according to claim 1.

18. The electromagnetic wave absorbing multilayer sheet according to claim 9, wherein the electromagnetic wave absorbing sheets are stacked and then pressed.

19. The electromagnetic wave absorbing multilayer sheet according to claim 9, wherein the electromagnetic wave absorbing sheets are stacked and then hot-pressed.
